(19) United States
(12) Patent Application Publication
(10) Pub. No.: US 2026/0203475 A1
(43) Pub. Date: Jul. 16, 2026

(54) AUTOMATED VALIDATION OF ICONOGRAPHY IN ENTERPRISE SYSTEM

(71) Applicant: Dell Products L.P., Round Rock, TX (US)

(72) Inventors: David Sydow, Merrimack, NH (US); Dev Kathuria, Greater Noida (IN); Vivek Bhargava, Bangalore (IN); Abhishek Mishra, Bangalore (IN)

(73) Assignee: Dell Products L.P., Round Rock, TX (US)

(21) Appl. No.: 19/023,848

(22) Filed: Jan. 16, 2025

(51) Int. Cl. G06F 30/27; G06V 10/774; G06V 10/82

(52) U.S. Cl. CPC G06F 30/27; G06V 10/774; G06V 10/82

(57) ABSTRACT

Methods, system, and non-transitory processor-readable storage medium for UI iconography validation system are provided herein. An example method includes receiving, by a user interface (UI) iconography validation system, a plurality of icons under test. The UI iconography validation system creates tuples by pairing each icon under test with each valid icon from an icon database and processes the created tuples through a trained Siamese neural network model to generate matching scores. The UI iconography validation system determines a validation status of each icon under test based on the matching scores, where an icon is validated if any of its tuples generates a positive matching score and flags icons that fail to generate any positive matching scores as invalid icons.

### FIELD

The field relates generally to validating user interface components, for design and brand guidelines, on a web page.

### BACKGROUND

Companies have many applications that are released on a periodical basis into production and are made available to their customers and employees. Before going to production, all the development teams involved in the development of the application should be compliant with user interface fundamentals, while at the same time, adhering to design and brand guidelines along with accessibility standards.

### SUMMARY

Illustrative embodiments provide techniques for implementing a user interface (UI) iconography validation system in a storage system. For example, illustrative embodiments comprise a UI iconography validation system receiving a plurality of icons under test. The UI iconography validation system creates tuples by pairing each icon under test with each valid icon from an icon database and processes the created tuples through a trained Siamese neural network model to generate matching scores. The UI iconography validation system determines a validation status of each icon under test based on the matching scores, where an icon is validated if any of its tuples generates a positive matching score and flags icons that fail to generate any positive matching scores as invalid icons. Other types of processing devices can be used in other embodiments. These and other illustrative embodiments include, without limitation, apparatus, systems, methods and processor-readable storage media.

### BRIEF DESCRIPTION OF THE DRAWINGS

FIG. 1 shows an information processing system including a UI iconography validation system, in an illustrative embodiment.

FIG. 2 shows a flow diagram of a process for a UI iconography validation system, in an illustrative embodiment.

FIG. 3 illustrates an example Siamese Neural Network, in an illustrative embodiment.

FIGS. 4 and 5 show examples of processing platforms that may be utilized to implement at least a portion of a UI iconography validation system embodiments.

### DETAILED DESCRIPTION

Illustrative embodiments will be described herein with reference to exemplary computer networks and associated computers, servers, network devices or other types of processing devices. It is to be appreciated, however, that these and other embodiments are not restricted to use with the particular illustrative network and device configurations shown. Accordingly, the term “computer network” as used herein is intended to be broadly construed, so as to encompass, for example, any system comprising multiple networked processing devices.

Described below is a technique for use in implementing a UI iconography validation system, which technique may be used to receive, by a UI iconography validation system, a plurality of icons under test. The UI iconography validation system creates tuples by pairing each icon under test with each valid icon from an icon database and processes the created tuples through a trained Siamese neural network model to generate matching scores. The UI iconography validation system determines a validation status of each icon under test based on the matching scores, where an icon is validated if any of its tuples generates a positive matching score and flags icons that fail to generate any positive matching scores as invalid icons.

Typically, there is a long process for validation of software applications across various development teams before the software is ready for production deployment. The last step of the process is where the UI is manually validated against preset company design guidelines.

Despite consuming significant time and efforts, manual validation of software applications often overlooks the subtleties that may escape the human eye, such as specific color codes, precise typographical alignments, pixel-perfect icon placements, component spacings, and other minor but significant design elements. This causes visual inconsistencies or discrepancies in the code that leads to delays in the GTM (Go To Market) process and ultimately leads to delay in the software application's release-cycle.

Conventional technologies that manually validate UI iconography standards result in a time-consuming effort requiring significant back and forth efforts of teams before the software is ready for production, for example, a team that validates if the icons meet the basic company standards, a GTM team whose focus is getting the software application out in the market, and a branding and compliance team. The application development team provides the software code and binary files to these teams, and each team validates independently. Having multiple teams involved in the verification process causes long lead times. This causes delays in the GTM process and ultimately leads to delay in the software's release-cycle. Conventional technologies that manually validate UI iconography standards can be unreliable. For example, manual validation for each icon on a screen requires verifying that each icon matches icons in the company database. There may be pixel-by-pixel comparison that fails to account for distortion such as sizing, or minor insignificant changes to the theme of the icon. Icons are smaller images, typically 128×128 pixels. When they are distorted, they still can convey valid meaning because they are smaller images. Conventional technologies for validating UI iconography standards increase the cost of software production by increasing the iterations required within the development cycle to manually validate the software with regard to UI iconography standards. Conventional technologies that use manual validation may miss important patches or feature releases due to the increased lead times.

By contrast, in at least some implementations in accordance with the current technique as described herein, UI iconography standards are validated by a UI iconography validation system that receives a plurality of icons under test. The UI iconography validation system creates tuples by pairing each icon under test with each valid icon from an icon database and processes the created tuples through a trained Siamese neural network model to generate matching scores. The UI iconography validation system determines a validation status of each icon under test based on the matching scores, where an icon is validated if any of its tuples generates a positive matching score and flags icons that fail to generate any positive matching scores as invalid icons.

Thus, a goal of the current technique is to provide a method and a system for providing a UI iconography validation system that validates UI iconography standards. Another goal is to automate the manual process and provide a system that is flexible to account for both distortions in scale and minor changes to the overall theme of the icon. Another goal is to account for distortion such as sizing, or minor insignificant changes to the theme of the icon that might not be meaningful to a user's eye. Another goal is to use machine learning to accept icons that are close enough to convey similar meaning, but do not have to be the same at a pixel-by-pixel level. Yet another goal is to provide a UI iconography validation system that can be integrated with DevOps processes to validate iconography on a UI using machine learning techniques to account for distortion and minor thematic changes.

In at least some implementations in accordance with the current technique described herein, the use of a UI iconography validation system can provide one or more of the following advantages: providing a method and a system that validates UI iconography standards, automating the manual process, providing a system that is flexible to account for both distortions in scale and minor changes to the overall theme of the icon, accounting for distortion such as sizing, or minor insignificant changes to the theme of the icon that might not be meaningful to a user's eye, using machine learning to accept icons that are close enough to convey similar meaning, but do not have to be the same at a pixel-by-pixel level, and providing a UI iconography validation system that can be integrated with DevOps processes to validate iconography on a UI using machine learning techniques to account for distortion and minor thematic changes.

In contrast to conventional technologies, in at least some implementations in accordance with the current technique as described herein, UI iconography standards are validated by a UI iconography validation system that receives a plurality of icons under test. The UI iconography validation system creates tuples by pairing each icon under test with each valid icon from an icon database and processes the created tuples through a trained Siamese neural network model to generate matching scores. The UI iconography validation system determines a validation status of each icon under test based on the matching scores, where an icon is validated if any of its tuples generates a positive matching score and flags icons that fail to generate any positive matching scores as invalid icons.

In an example embodiment of the current technique, the UI iconography validation system transmits a validation status of each icon under test to a build stage associated with a Continuous Integration/Continuous Delivery (CI/CD) pipeline runner system.

In an example embodiment of the current technique, a Continuous Integration/Continuous Delivery (CI/CD) pipeline runner system receives the plurality of the icon under test.

In an example embodiment of the current technique, the icon database comprises valid icons that adhere to preset company design guidelines.

In an example embodiment of the current technique, the UI iconography validation system creates a list of tuples of size N*R where N represents the plurality of the icon under test and R represents each valid icon from the icon database.

In an example embodiment of the current technique, the UI iconography validation system passes the created tuples as input into the Siamese neural network.

In an example embodiment of the current technique, the UI iconography validation system trains a Siamese neural network model by distorting each valid icon from the icon database.

In an example embodiment of the current technique, the UI iconography validation system generates distorted versions of each valid icon from the icon database using sinusoidal distortion and scale distortion ranging from 10% to 50%, creates training tuples by pairing each valid icon with their distorted versions, labels the training tuples as positive matches for same-icon pairs and negative matches for different-icon pairs and trains the Siamese neural network model using the labeled training tuples.

In an example embodiment of the current technique, the UI iconography validation system the sinusoidal distortion is applied in increments of 10% up to 50% distortion to generate five distorted versions of each valid icon.

In an example embodiment of the current technique, the scale distortion comprises width distortion applied in increments of 10% up to 50% to generate five width-distorted versions of each valid icon.

In an example embodiment of the current technique, the scale distortion comprises height distortion applied in increments of 10% up to 50% to generate five height-distorted versions of each valid icon.

In an example embodiment of the current technique, the UI iconography validation system pairs each valid icon with every other valid icon in the icon database according to a permutation formula.

In an example embodiment of the current technique, the Siamese neural network model comprises mirrored Convolutional Neural Networks for image processing.

In an example embodiment of the current technique, the Convolutional Neural Networks accept an input shape of 128×128×1 pixels.

In an example embodiment of the current technique, the matching scores comprise binary outputs, with 1 indicating a positive match and 0 indicating a negative match.

In an example embodiment of the current technique, the Siamese neural network model compares each icon under test with each valid icon from an icon database.

In an example embodiment of the current technique, the Siamese neural network model compares icons using binary cross-entropy.

In an example embodiment of the current technique, the UI iconography validation system designates an icon under test as a validated icon if an output of the Siamese neural network is a 1.

In an example embodiment of the current technique, the UI iconography validation system designates an icon under test as a validated icon if the icon is similar to a valid icon in the icon database where the valid icon serves as approved comparison standards for icon validation and where the valid icon establishes acceptable visual characteristics for icon validation without requiring pixel-perfect matching.

In an example embodiment of the current technique, the UI iconography validation system avoids designating an icon under test as an invalidated icon due to a distortion associated with the icon under test.

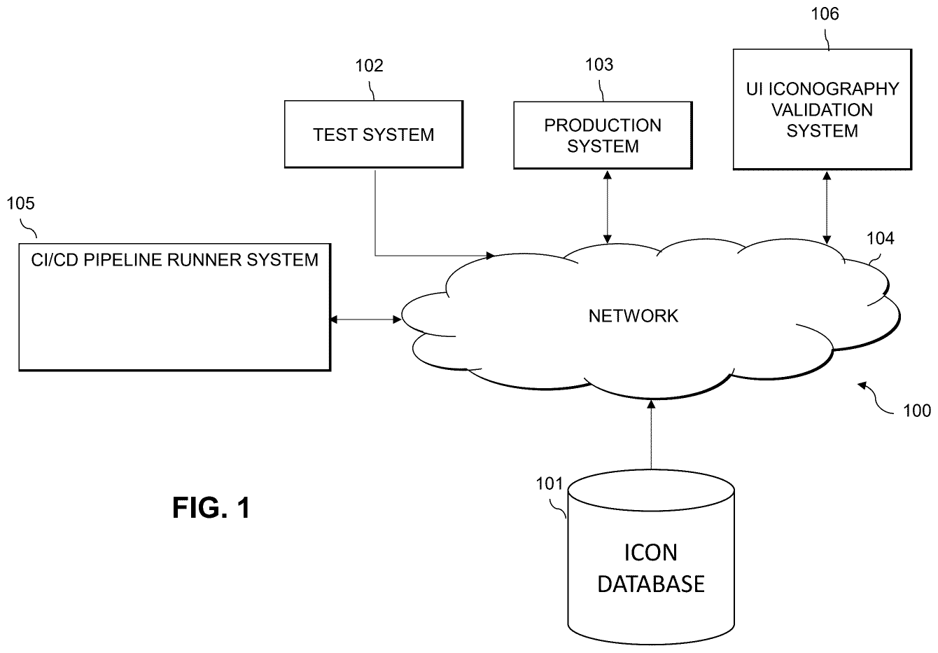

FIG. 1 shows a computer network (also referred to herein as an information processing system) 100 configured in accordance with an illustrative embodiment. The computer network 100 comprises a Continuous Integration/Continuous Delivery (CI/CD) pipeline system 105, a test system 102, a production system 103, a UI iconography validation system 106, and an icon database 101. In an example embodiment, CI/CD as that term is used herein refers generally to continuous integration, continuous deployment and/or continuous delivery. Such functions or portions thereof are considered to be examples of a “software development process” as that term is broadly used herein. A wide variety of other types of software development processes may be utilized in other embodiments, illustratively relating to integration, deployment and/or other aspects of software development for one or more of the source code that is executed on the test system 102, production system 103, or other systems. The CI/CD pipeline system 105, test system 102, production system 103, UI iconography validation system 106, and icon database 101 are coupled to a network 104, where the network 104 in this embodiment is assumed to represent a sub-network or other related portion of the larger computer network 100. Accordingly, elements 100 and 104 are both referred to herein as examples of “networks,” but the latter is assumed to be a component of the former in the context of the FIG. 1 embodiment. Also coupled to network 104 is a UI iconography validation system 106 that may reside on a storage system. Such storage systems can comprise any of a variety of different types of storage including network-attached storage (NAS), storage area networks (SANs), direct-attached storage (DAS) and distributed DAS, as well as combinations of these and other storage types, including software-defined storage.

Each of the CI/CD pipeline system 105, test system 102, production system 103, UI iconography validation system 106, and icon database 101 may comprise, for example, servers and/or portions of one or more server systems, as well as devices such as mobile telephones, laptop computers, tablet computers, desktop computers or other types of computing devices. Such devices are examples of what are more generally referred to herein as “processing devices.” Some of these processing devices are also generally referred to herein as “computers.”

The CI/CD pipeline system 105, test system 102, production system 103, UI iconography validation system 106, and icon database 101 in some embodiments comprise respective computers associated with a particular company, organization or other enterprise. In addition, at least portions of the computer network 100 may also be referred to herein as collectively comprising an “enterprise network.” Numerous other operating scenarios involving a wide variety of different types and arrangements of processing devices and networks are possible, as will be appreciated by those skilled in the art.

Also, it is to be appreciated that the term “user” in this context and elsewhere herein is intended to be broadly construed so as to encompass, for example, human, hardware, software or firmware entities, as well as various combinations of such entities.

The network 104 is assumed to comprise a portion of a global computer network such as the Internet, although other types of networks can be part of the computer network 100, including a wide area network (WAN), a local area network (LAN), a satellite network, a telephone or cable network, a cellular network, a wireless network such as a Wi-Fi or WiMAX network, or various portions or combinations of these and other types of networks. The computer network 100 in some embodiments therefore comprises combinations of multiple different types of networks, each comprising processing devices configured to communicate using internet protocol (IP) or other related communication protocols.

Also associated with the UI iconography validation system 106 are one or more input-output devices, which illustratively comprise keyboards, displays or other types of input-output devices in any combination. Such input-output devices can be used, for example, to support one or more user interfaces to the UI iconography validation system 106, as well as to support communication between the UI iconography validation system 106 and other related systems and devices not explicitly shown. For example, a dashboard may be provided for a user to view a progression of the execution of the UI iconography validation system 106. One or more input-output devices may also be associated with any of the CI/CD pipeline system 105, test system 102, production system 103, UI iconography validation system 106, and icon database 101.

Additionally, the UI iconography validation system 106 in the FIG. 1 embodiment is assumed to be implemented using at least one processing device. Each such processing device generally comprises at least one processor and an associated memory, and implements one or more functional modules for controlling certain features of the UI iconography validation system 106. More particularly, the UI iconography validation system 106 in this embodiment can comprise a processor coupled to a memory and a network interface. The processor illustratively comprises a microprocessor, a microcontroller, an application-specific integrated circuit (ASIC), a field-programmable gate array (FPGA) or other type of processing circuitry, as well as portions or combinations of such circuitry elements.

The memory illustratively comprises random access memory (RAM), read-only memory (ROM) or other types of memory, in any combination. The memory and other memories disclosed herein may be viewed as examples of what are more generally referred to as “processor-readable storage media” storing executable computer program code or other types of software programs.

One or more embodiments include articles of manufacture, such as computer-readable storage media. Examples of an article of manufacture include, without limitation, a storage device such as a storage disk, a storage array or an integrated circuit containing memory, as well as a wide variety of other types of computer program products. The term “article of manufacture” as used herein should be understood to exclude transitory, propagating signals. These and other references to “disks” herein are intended to refer generally to storage devices, including solid-state drives (SSDs), and should therefore not be viewed as limited in any way to spinning magnetic media.

The network interface allows the UI iconography validation system 106 to communicate over the network 104 with the CI/CD pipeline system 105, test system 102, production system 103, and icon database 101 and illustratively comprises one or more conventional transceivers.

A UI iconography validation system 106 may be implemented at least in part in the form of software that is stored in memory and executed by a processor, and may reside in any processing device. The UI iconography validation system 106 may be a standalone plugin that may be included within a processing device.

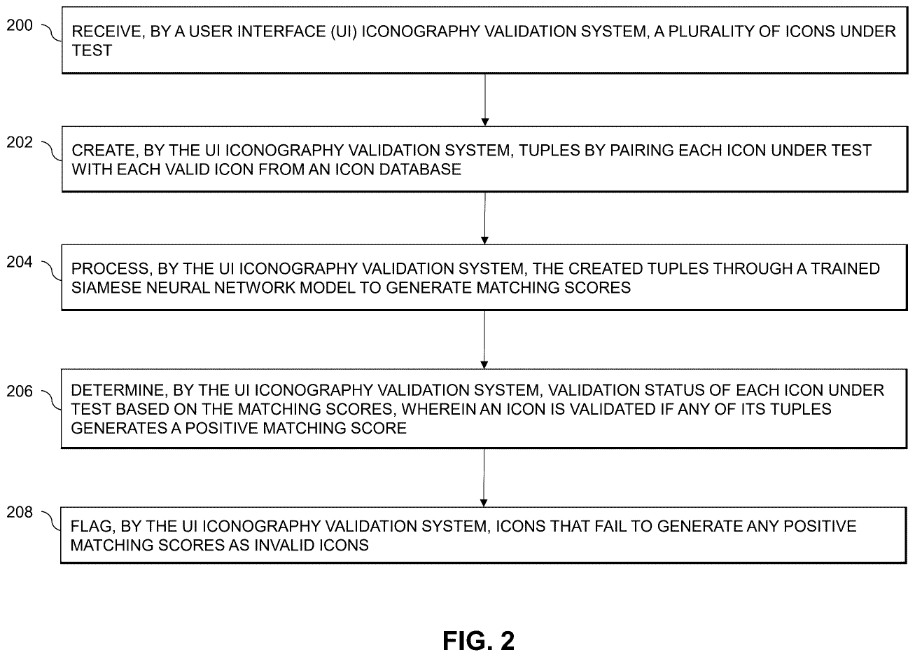

It is to be understood that the particular set of elements shown in FIG. 1 for UI iconography validation system 106 involving the CI/CD pipeline system 105, test system 102, production system 103, and icon database 101 of computer network 100 is presented by way of illustrative example only, and in other embodiments additional or alternative elements may be used. Thus, another embodiment includes additional or alternative systems, devices and other network entities, as well as different arrangements of modules and other components. For example, in at least one embodiment, one or more of the UI iconography validation system 106 can be on and/or part of the same processing platform. An exemplary process of UI iconography validation system 106 in computer network 100 will be described in more detail with reference to, for example, the flow diagram of FIG. 2.

FIG. 2 is a flow diagram of a process for execution of the UI iconography validation system 106 in an illustrative embodiment. It is to be understood that this particular process is only an example, and additional or alternative processes can be carried out in other embodiments.

At 200, a UI iconography validation system 106 receives a plurality of icons under test. In an example embodiment, the plurality of icons under test is a plurality of user interface icons under test. In an example embodiment, a CI/CD pipeline runner system 105 receives the plurality of icons under test. A CI/CD pipeline runner system 105 automates a software delivery process, and typically comprises a set of automated processes and tools that allow developers and an operations team to work together to generate and deploy application software code to a production environment. A CI/CD pipeline runner system 105 may comprise a specified set of elements and/or environments. Such elements and/or environments may be added or removed from the CI/CD pipeline runner system 105, for example, based at least in part on the software and/or compliance requirements. A CI/CD pipeline runner system 105 typically comprises one or more quality control gates to ensure that software code does not get released to a production environment without satisfying a number of predefined testing and/or quality requirements. For example, a quality control gate may specify that software code should compile without errors and that all unit tests and functional user interface tests must pass.

The CI/CD pipeline runner system 105 may comprise, for example, a commercially-available CI/CD system such as Jenkins, Jira, and/or other types of DevOps tools, suitably modified in the manner disclosed herein to provide software development processes utilizing the UI iconography validation system 106 to validate UI iconography standards. In an example embodiment, the code files (i.e., the source code) are retrieved from a code repository.

At 202, the UI iconography validation system 106 creates tuples by pairing each icon under test with each valid icon from an icon database 101. In an example embodiment, the UI iconography validation system 106 creates a list of all the icons under test, for example, I_{Test1}, I_{Test2}, . . . . I_{TestN}. The icons under test may comprise all icons and images in a user interface that is under test, or in other words, all the objects under test.

In an example embodiment, the UI iconography validation system 106 creates a list of tuples of size N*R where N represents the plurality of the icons under test and R represents each valid icon from the icon database 101. In an example embodiment, the icon database 101 comprises valid icons that adhere to preset company design guidelines. For each of the list of icon under test (i.e., I_{Test1}, I_{Test2}, . . . . I_{TestN}), the UI iconography validation system 106 creates a tuple against each of the icons in the icon database 101. For example, the icons in the icon database 101 may be the icons in a company database against which to validate each of the icons and images in a user interface that is under test. The resulting list of tuples is of size N*R, where N is the number of icons under test and R is the number of icons in the icon database 101. For example, the icon database 101 may contain Icon₁, Icon₂, and Icon₃. The list of icons under test (or objects under test) may comprise I_{Test1} and I_{Test2}. The UI iconography validation system 106 creates tuples (I_{Test1}, Icon₁), (I_{Test1}, Icon₂), (I_{Test1}, Icon₃), (I_{Test2}, Icon₁), (I_{Test2}, Icon₂), (I_{Test2}, Icon₃).

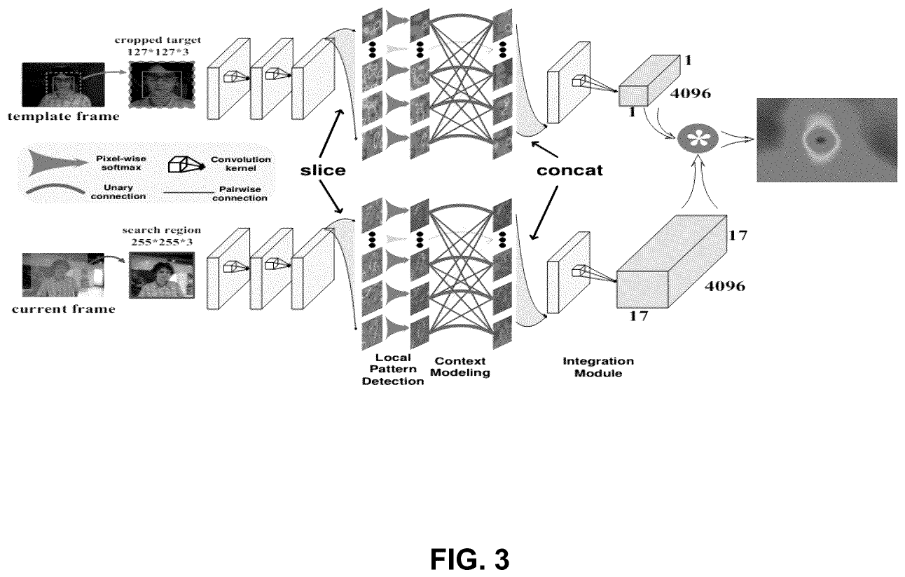

At 204, the UI iconography validation system 106 processes the created tuples through a trained Siamese neural network model to generate matching scores. FIG. 3 illustrates an example Siamese Neural Network. In an example embodiment, the Siamese neural network model compares each icon under test with each valid icon from an icon database 101. In an example embodiment, the Siamese neural network model performs the comparison using binary cross-entropy. In an example embodiment, the Siamese neural network model comprises mirrored Convolutional Neural Networks for image processing. In an example embodiment, the Convolutional Neural Networks accept an input shape of 128×128×1 pixels.

In an example embodiment, the UI iconography validation system 106 passes the created tuples as input into the Siamese neural network (i.e., the trained Siamese neural network). In an example embodiment, the matching scores comprise binary outputs, with 1 indicating a positive match (i.e., a matching image in the tuple) and 0 indicating a negative match (i.e., a non-matching image in the tuple).

In an example embodiment, the UI iconography validation system 106 trains the Siamese neural network model by distorting each valid icon from the icon database 101. In an example embodiment, the UI iconography validation system 106 iterates through a list of all valid UI iconography in the icon database 101, for example, a company database. For each valid UI iconography in the icon database 101, the UI iconography validation system 106 generates distorted versions of each valid icon from the icon database 101 using sinusoidal distortion and scale distortion ranging from 10% to 50%.

In an example embodiment, the sinusoidal distortion is applied in increments of 10% up to 50% distortion to generate five distorted versions of each valid icon. For example, each of the valid icons is distorted using sinusoidal distortion from 10%, incrementing by 10% until 50% distortion is achieved. For example, the UI iconography validation system 106 generates 5 images at 10%, 20%, 30%, 40%, and 50% distortion respectively. This facilitates classifying icon under test with slight distortion as valid icons.

In an example embodiment, the scale distortion comprises width distortion applied in increments of 10% up to 50% to generate five width-distorted versions of each valid icon. For example, each of the valid icons is distorted using width distortion from 10%, incrementing by 10% until 50% distortion is achieved. For example, the UI iconography validation system 106 generates 5 images at 10%, 20%, 30%, 40%, and 50% distortion respectively. This also facilitates classifying icon under test with slight distortion as valid icons.

In an example embodiment, the scale distortion comprises height distortion applied in increments of 10% up to 50% to generate five height-distorted versions of each valid icon. For example, each of the valid icons is distorted using height distortion from 10%, incrementing by 10% until 50% distortion is achieved. For example, the UI iconography validation system 106 generates 5 images at 10%, 20%, 30%, 40%, and 50% distortion respectively. This, again, facilitates classifying icon under test with slight distortion as valid icons.

Thus, the UI iconography validation system 106 generates 15 distorted images Icon₁, Icon₂, . . . . Icon₁₅ for each original valid icon image, “BaseIcon” in the icon database 101. In an example embodiment, the UI iconography validation system 106 creates training tuples by pairing each valid icon, BaseIcon with their distorted versions (i.e., Icon₁, Icon₂, . . . . Icon₁₅). Each tuple contains the following information: (BaseIcon, Icon_{N}).

In an example embodiment, the UI iconography validation system 106 pairs each valid icon in the icon database 101 as a tuple with all of the other valid icons in the icon database 101 (including itself), creating a total number of tuples according to a permutation formula:

$$nPr = n ! / ( n - r ) !$$

For example, if the icon database 101 contains Icon₁, Icon₂, and Icon₃, then the following training tuples are created, (Icon₁, Icon₁), (Icon₁, Icon₂), (Icon₁, Icon₃), (Icon₂, Icon₂), (Icon₂, Icon₃), and (Icon₃, Icon₃).

In an example embodiment, the UI iconography validation system 106 labels the training tuples as positive matches for same-icon pairs and negative matches for different-icon pairs. In an example embodiment, the UI iconography validation system 106 passes the training tuples into the Siamese neural network model with labels of a 1 (for positive matches) or 0 (for negative matches). For example, all training tuples that contain the same Icon_{N}, such as (Icon₁, Icon₁) are labeled as positive matches. All other values are labeled as 0, or negative matches.

In an example embodiment, the UI iconography validation system 106 trains the Siamese neural network model using the labeled training tuples. In an example embodiment, the training tuples are split into a training group and a testing group. In an example embodiment, 70% of the training tuples are assigned to the training group and 30% of the training tuples are assigned to the testing group. In an example embodiment, the Siamese neural network model training is performed for 100 epochs.

At 206, the UI iconography validation system 106 determines a validation status of each icon under test based on the matching scores, where an icon is validated if any of its tuples generates a positive matching score. In an example embodiment, the UI iconography validation system 106 designates an icon under test as a validated icon if an output of the Siamese neural network (i.e., the trained Siamese neural network) is a 1. In other words, if any of the tuples for each I_{TestN} item contains a 1, then that I_{TestN} icon is counted as a validated icon. If not, the I_{TestN} icon is flagged as an invalid icon.

In an example embodiment, the UI iconography validation system 106 designates an icon under test as a validated icon if the icon is similar to a valid icon in the icon database 101. Here, a valid icon serves as approved comparison standards for icon validation, and establishes acceptable visual characteristics for icon validation without requiring pixel-perfect matching. In other words, a validated icon does not have to be the same at a pixel-by-pixel level. Further, the UI iconography validation system 106 avoids designating an icon under test as an invalidated icon due to a distortion associated with the icon under test.

At 208, the UI iconography validation system 106 flags icons that fail to generate any positive matching scores as invalid icons.

In an example embodiment, the UI iconography validation system 106 transmits a validation status of each icon under test to a build stage associated with a Continuous Integration/Continuous Delivery (CI/CD) pipeline runner system 105. In an example embodiment, the UI iconography validation system 106 transmits the validated source code associated with the UI under test to a build stage associated with the CI/CD pipeline runner system 105.

In an example embodiment, the UI iconography validation system 106 is invoked within the CI/CD pipeline runner system 105 early in the pipeline before the build stage. The UI iconography validation system 106 performs the icon validation process for each icon under test. After the UI iconography validation system 106 has completed the validation process, the validated icons under test, or a list of the validated icons under test, are transmitted from the UI iconography validation system 106 to the build stage in the CI/CD pipeline runner system 105.

Accordingly, the particular processing operations and other functionality described in conjunction with the flow diagram of FIG. 2 are presented by way of illustrative example only, and should not be construed as limiting the scope of the disclosure in any way. For example, the ordering of the process steps may be varied in other embodiments, or certain steps may be performed concurrently with one another rather than serially.

The above-described illustrative embodiments provide significant advantages relative to conventional approaches. For example, some embodiments are configured to provide a method and a system for providing a UI iconography validation system that validates UI iconography standards. These and other embodiments can effectively improve UI iconography standards validation relative to conventional approaches. For example, embodiments disclosed herein automate the manual process of validating iconography. Embodiments disclosed herein provide a system that is flexible to account for both distortions in scale and minor changes to the overall theme of the icon. Embodiments disclosed herein account for distortion such as sizing, or minor insignificant changes to the theme of the icon that might not be meaningful to a user's eye. Embodiments disclosed herein use machine learning to accept icons that are close enough to convey similar meaning, but do not have to be the same at a pixel-by-pixel level. Embodiments disclosed herein provide a UI iconography validation system that can be integrated with DevOps processes to validate iconography on a UI using machine learning techniques to account for distortion and minor thematic changes.

It is to be appreciated that the particular advantages described above and elsewhere herein are associated with particular illustrative embodiments and need not be present in other embodiments. Also, the particular types of information processing system features and functionality as illustrated in the drawings and described above are exemplary only, and numerous other arrangements may be used in other embodiments.

As mentioned previously, at least portions of the information processing system 100 can be implemented using one or more processing platforms. A given such processing platform comprises at least one processing device comprising a processor coupled to a memory. The processor and memory in some embodiments comprise respective processor and memory elements of a virtual machine or container provided using one or more underlying physical machines. The term “processing device” as used herein is intended to be broadly construed so as to encompass a wide variety of different arrangements of physical processors, memories and other device components as well as virtual instances of such components. For example, a “processing device” in some embodiments can comprise or be executed across one or more virtual processors. Processing devices can therefore be physical or virtual and can be executed across one or more physical or virtual processors. It should also be noted that a given virtual device can be mapped to a portion of a physical one.

Some illustrative embodiments of a processing platform used to implement at least a portion of an information processing system comprises cloud infrastructure including virtual machines implemented using a hypervisor that runs on physical infrastructure. The cloud infrastructure further comprises sets of applications running on respective ones of the virtual machines under the control of the hypervisor. It is also possible to use multiple hypervisors each providing a set of virtual machines using at least one underlying physical machine. Different sets of virtual machines provided by one or more hypervisors may be utilized in configuring multiple instances of various components of the system.

These and other types of cloud infrastructure can be used to provide what is also referred to herein as a multi-tenant environment. One or more system components, or portions thereof, are illustratively implemented for use by tenants of such a multi-tenant environment.

As mentioned previously, cloud infrastructure as disclosed herein can include cloud-based systems. Virtual machines provided in such systems can be used to implement at least portions of a computer system in illustrative embodiments.

In some embodiments, the cloud infrastructure additionally or alternatively comprises a plurality of containers implemented using container host devices. For example, as detailed herein, a given container of cloud infrastructure illustratively comprises a Docker container or other type of Linux Container (LXC). The containers are run on virtual machines in a multi-tenant environment, although other arrangements are possible. The containers are utilized to implement a variety of different types of functionality within the information processing system 100. For example, containers can be used to implement respective processing devices providing compute and/or storage services of a cloud-based system. Again, containers may be used in combination with other virtualization infrastructure such as virtual machines implemented using a hypervisor.

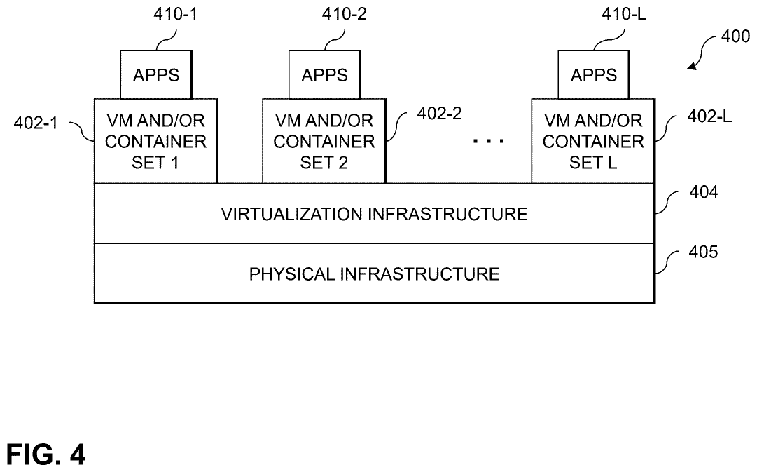

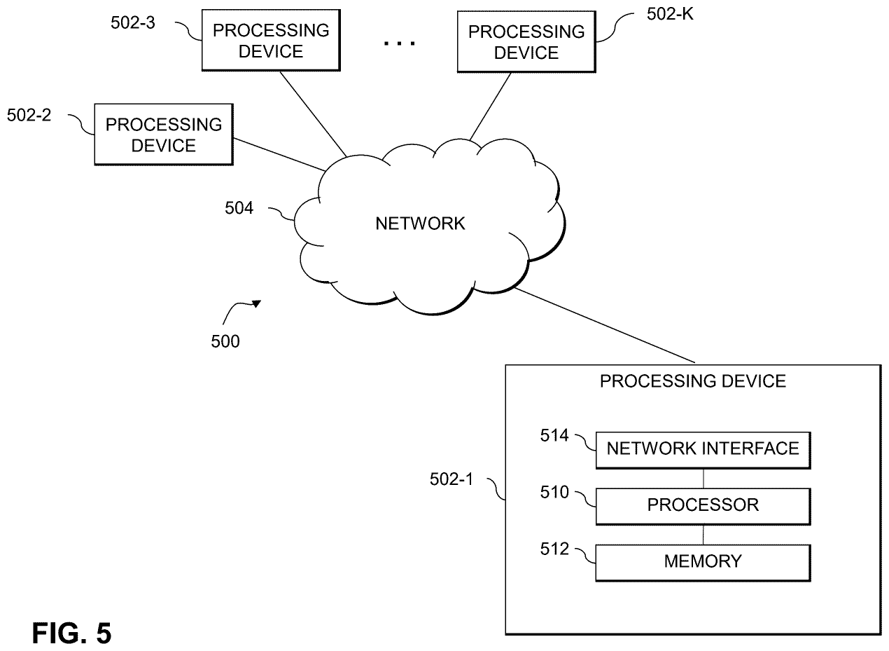

Illustrative embodiments of processing platforms will now be described in greater detail with reference to FIGS. 4 and 5. Although described in the context of the information processing system 100, these platforms may also be used to implement at least portions of other information processing systems in other embodiments.

FIG. 4 shows an example processing platform comprising cloud infrastructure 400. The cloud infrastructure 400 comprises a combination of physical and virtual processing resources that are utilized to implement at least a portion of the information processing system 100. The cloud infrastructure 400 comprises multiple virtual machines (VMs) and/or container sets 402-1, 402-2, . . . 402-L implemented using virtualization infrastructure 404. The virtualization infrastructure 404 runs on physical infrastructure 405, and illustratively comprises one or more hypervisors and/or operating system level virtualization infrastructure. The operating system level virtualization infrastructure illustratively comprises kernel control groups of a Linux operating system or other type of operating system.

The cloud infrastructure 400 further comprises sets of applications 410-1, 410-2, . . . 410-L running on respective ones of the VMs/container sets 402-1, 402-2, . . . 402-L under the control of the virtualization infrastructure 404. The VMs/container sets 402 comprise respective VMs, respective sets of one or more containers, or respective sets of one or more containers running in VMs. In some implementations of the FIG. 4 embodiment, the VMs/container sets 402 comprise respective VMs implemented using virtualization infrastructure 404 that comprises at least one hypervisor.

A hypervisor platform may be used to implement a hypervisor within the virtualization infrastructure 404, where the hypervisor platform has an associated virtual infrastructure management system. The underlying physical machines comprise one or more distributed processing platforms that include one or more storage systems.

In other implementations of the FIG. 4 embodiment, the VMs/container sets 402 comprise respective containers implemented using virtualization infrastructure 404 that provides operating system level virtualization functionality, such as support for Docker containers running on bare metal hosts, or Docker containers running on VMs. The containers are illustratively implemented using respective kernel control groups of the operating system.

As is apparent from the above, one or more of the processing modules or other components of the information processing system 100 may each run on a computer, server, storage device or other processing platform element. A given such element is viewed as an example of what is more generally referred to herein as a “processing device.” The cloud infrastructure 400 shown in FIG. 4 may represent at least a portion of one processing platform. Another example of such a processing platform is processing platform 500 shown in FIG. 5.

The processing platform 500 in this embodiment comprises a portion of the information processing system 100 and includes a plurality of processing devices, denoted 502-1, 502-2, 502-3, . . . 502-K, which communicate with one another over a network 504.

The network 504 comprises any type of network, including by way of example a global computer network such as the Internet, a WAN, a LAN, a satellite network, a telephone or cable network, a cellular network, a wireless network such as a Wi-Fi or WiMAX network, or various portions or combinations of these and other types of networks.

The processing device 502-1 in the processing platform 500 comprises a processor 510 coupled to a memory 512.

The processor 510 comprises a microprocessor, a microcontroller, an application-specific integrated circuit (ASIC), a field-programmable gate array (FPGA) or other type of processing circuitry, as well as portions or combinations of such circuitry elements.

The memory 512 comprises random access memory (RAM), read-only memory (ROM) or other types of memory, in any combination. The memory 512 and other memories disclosed herein should be viewed as illustrative examples of what are more generally referred to as “processor-readable storage media” storing executable program code of one or more software programs.

Articles of manufacture comprising such processor-readable storage media are considered illustrative embodiments. A given such article of manufacture comprises, for example, a storage array, a storage disk or an integrated circuit containing RAM, ROM or other electronic memory, or any of a wide variety of other types of computer program products. The term “article of manufacture” as used herein should be understood to exclude transitory, propagating signals. Numerous other types of computer program products comprising processor-readable storage media can be used.

Also included in the processing device 502-1 is network interface circuitry 514, which is used to interface the processing device with the network 504 and other system components, and may comprise conventional transceivers.

The other processing devices 502 of the processing platform 500 are assumed to be configured in a manner similar to that shown for processing device 502-1 in the figure.

Again, the particular processing platform 500 shown in the figure is presented by way of example only, and the information processing system 100 may include additional or alternative processing platforms, as well as numerous distinct processing platforms in any combination, with each such platform comprising one or more computers, servers, storage devices or other processing devices.

For example, other processing platforms used to implement illustrative embodiments can comprise different types of virtualization infrastructure, in place of or in addition to virtualization infrastructure comprising virtual machines. Such virtualization infrastructure illustratively includes container-based virtualization infrastructure configured to provide Docker containers or other types of LXCs.

As another example, portions of a given processing platform in some embodiments can comprise converged infrastructure.

It should therefore be understood that in other embodiments different arrangements of additional or alternative elements may be used. At least a subset of these elements may be collectively implemented on a common processing platform, or each such element may be implemented on a separate processing platform.

Also, numerous other arrangements of computers, servers, storage products or devices, or other components are possible in the information processing system 100. Such components can communicate with other elements of the information processing system 100 over any type of network or other communication media.

For example, particular types of storage products that can be used in implementing a given storage system of a distributed processing system in an illustrative embodiment include all-flash and hybrid flash storage arrays, scale-out all-flash storage arrays, scale-out NAS clusters, or other types of storage arrays. Combinations of multiple ones of these and other storage products can also be used in implementing a given storage system in an illustrative embodiment.

It should again be emphasized that the above-described embodiments are presented for purposes of illustration only. Many variations and other alternative embodiments may be used. Also, the particular configurations of system and device elements and associated processing operations illustratively shown in the drawings can be varied in other embodiments. Thus, for example, the particular types of processing devices, modules, systems and resources deployed in a given embodiment and their respective configurations may be varied. Moreover, the various assumptions made above in the course of describing the illustrative embodiments should also be viewed as exemplary rather than as requirements or limitations of the disclosure. Numerous other alternative embodiments within the scope of the appended claims will be readily apparent to those skilled in the art.

What is claimed is:

1. A method comprising:
receiving, by a user interface (UI) iconography validation system, a plurality of icons under test;
creating, by the UI iconography validation system, tuples by pairing each icon under test with each valid icon from an icon database;
processing, by the UI iconography validation system, the created tuples through a trained Siamese neural network model to generate matching scores;
determining, by the UI iconography validation system, a validation status of each icon under test based on the matching scores, wherein an icon is validated if any of its tuples generates a positive matching score; and
flagging, by the UI iconography validation system, icons that fail to generate any positive matching scores as invalid icons, wherein the method is performed by at least one processing device comprising a processor coupled to a memory.

2. The method of claim 1 further comprising:
transmitting a validation status of each icon under test to a build stage associated with a Continuous Integration/Continuous Delivery (CI/CD) pipeline runner system.

3. The method of claim 1 wherein receiving the plurality of icons under test comprises:
receiving, by a Continuous Integration/Continuous Delivery (CI/CD) pipeline runner system, the plurality of the icon under test.

4. The method of claim 1 wherein the icon database comprises valid icons that adhere to preset company design guidelines.

5. The method of claim 1 wherein creating the tuples comprises:
creating a list of tuples of size N*R wherein N represents the plurality of the icon under test and R represents each valid icon from the icon database.

6. The method of claim 1 wherein processing the tuples comprises:
passing the created tuples as input into the Siamese neural network.

7. The method of claim 1 wherein processing the tuples comprises:
training a Siamese neural network model by distorting each valid icon from the icon database.

8. The method of claim 7 wherein training the Siamese neural network model comprises:
generating distorted versions of each valid icon from the icon database using sinusoidal distortion and scale distortion ranging from 10% to 50%;
creating training tuples by pairing each valid icon with their distorted versions;
labeling the training tuples as positive matches for same-icon pairs and negative matches for different-icon pairs; and
training the Siamese neural network model using the labeled training tuples.

9. The method of claim 8 wherein the sinusoidal distortion is applied in increments of 10% up to 50% distortion to generate five distorted versions of each valid icon.

10. The method of claim 8 wherein the scale distortion comprises width distortion applied in increments of 10% up to 50% to generate five width-distorted versions of each valid icon.

11. The method of claim 8 wherein the scale distortion comprises height distortion applied in increments of 10% up to 50% to generate five height-distorted versions of each valid icon.

12. The method of claim 8 wherein creating the training tuples comprises:
pairing each valid icon with every other valid icon in the icon database according to a permutation formula.

13. The method of claim 1 wherein the Siamese neural network model comprises mirrored Convolutional Neural Networks for image processing.

14. The method of claim 13 wherein the Convolutional Neural Networks accept an input shape of 128×128×1 pixels.

15. The method of claim 1 wherein the matching scores comprise binary outputs, with 1 indicating a positive match and 0 indicating a negative match.

16. The method of claim 1 wherein the Siamese neural network model compares each icon under test with each valid icon from an icon database.

17. The method of claim 16 wherein the Siamese neural network model compares icons using binary cross-entropy.

18. The method of claim 1 wherein determining the validation status of each icon under test comprises:
designating an icon under test as a validated icon if the icon is similar to a valid icon in the icon database wherein the valid icon serves as approved comparison standards for icon validation and wherein the valid icon establishes acceptable visual characteristics for icon validation without requiring pixel-perfect matching.

19. A system comprising:
at least one processing device comprising a processor coupled to a memory;
the at least one processing device being configured:
to receive, by a user interface (UI) iconography validation system, a plurality of icons under test;
to create, by the UI iconography validation system, tuples by pairing each icon under test with each valid icon from an icon database;
to process, by the UI iconography validation system, the created tuples through a trained Siamese neural network model to generate matching scores;
to determine, by the UI iconography validation system, a validation status of each icon under test based on the matching scores, wherein an icon is validated if any of its tuples generates a positive matching score; and
to flag, by the UI iconography validation system, icons that fail to generate any positive matching scores as invalid icons.

20. A computer program product comprising a non-transitory processor-readable storage medium having stored therein program code of one or more software programs, wherein the program code when executed by at least one processing device causes said at least one processing device:
to receive, by a user interface (UI) iconography validation system, a plurality of icons under test;
to create, by the UI iconography validation system, tuples by pairing each icon under test with each valid icon from an icon database;
to process, by the UI iconography validation system, the created tuples through a trained Siamese neural network model to generate matching scores;
to determine, by the UI iconography validation system, a validation status of each icon under test based on the matching scores, wherein an icon is validated if any of its tuples generates a positive matching score; and
to flag, by the UI iconography validation system, icons that fail to generate any positive matching scores as invalid icons.
